(19) United States
(12) Patent Application Publication
(10) Pub. No.: US 2007/0291460 A1
(43) Pub. Date: Dec. 20, 2007

(54) EXPANSION CARD FOR THIN TYPE COMPUTER

(75) Inventor: Yu-Chen CHU, Taichung County (TW)

Correspondence Address: BROWDY AND NEIMARK, P.L.L.C.;624 NINTH STREET, NW, SUITE 300, WASHINGTON, DC, 20001-5303, US

(73) Assignee: Universal Scientific Industrial Co., Ltd., Tsao Tuen (TW)

(21) Appl. No.: 11/762,841

(22) Filed: Jun. 14, 2007

(30) Foreign Application Priority Data
Jun. 14, 2006 (TW) 95210408

(51) Int. Cl. H05K 7/14; H05K 7/18

(52) U.S. Cl. 361/801

(57) ABSTRACT

An expansion card for a thin type computer in which the expansion card includes a bracket for mounting to the housing of the thin type computer, a circuit board mounted on the bracket for electrically connecting to the motherboard, and a plug terminal mounted on the bracket and electrically connected to the circuit board. When the circuit board is connected to the motherboard, the vertical height of both of the bracket and the circuit board above the motherboard is less than 80 mm.

### BACKGROUND OF THE INVENTION

1. Field of the Invention

The present invention relates to a thin type computer and more specifically, to an expansion card for a thin type computer.

2. Description of the Related Art

Expansion cards are intensively used in computers and their peripheral apparatus to add additional functionality to computer systems. When an expansion card is used in a computer, it is electrically connected to the motherboard of the computer either directly or through adapter means to expand the function

There are thin type computers of height below 80 mm that allow installation of component parts in vertical direction. The bracket of a standard expansion card for regular computer has a height about 120.88 mm. An expansion card of this design is not practical for use in a thin type computer. There is known an expansion card suitable for use in a small-sized computer. The bracket of this design of expansion card has a height about 80.06 mm. An expansion card having this height is still not suitable for use in a thin type computer. Therefore, conventional expansion cards have a common drawback of high vertical height.

Further, conventional expansion cards are to be affixed to the housing of a computer with screws. It is inconvenient to affix an expansion card to the housing of a computer with screws in the limited space inside the housing.

Therefore, it is desirable to provide an expansion card that eliminates the aforesaid problems.

### SUMMARY OF THE INVENTION

The present invention has been accomplished under the circumstances in view. It is the main object of the present invention to provide an expansion card for a thin type computer, which allows easy installation, and has an height much smaller than the prior art design after installation of the expansion card.

To achieve this and other objects of the present invention, the expansion card for a thin type computer comprises a bracket, a circuit board and at least one plug terminal. The thin type computer has a housing and a motherboard mounted in the housing. The bracket is mounted to the housing of the thin type computer. The circuit board is mounted on the bracket for electrically connecting to the motherboard. The plug terminal is mounted on the bracket and electrically connected to the circuit board. When the circuit board is connected to the motherboard, the vertical height of both of the bracket and the circuit board above the motherboard is less than 80 mm. Therefore, the expansion card has a much lower height than the prior art design after installation. Further, the invention makes the installation of the expansion card easy and the use of the expansion card convenient.

### BRIEF DESCRIPTION OF THE DRAWINGS

FIG. 1 is a perspective view of an expansion card according to the present invention.

FIG. 2 is an exploded view of the expansion card according to the present invention.

FIG. 3 illustrates the expansion card installed in a thin type computer according to the present invention.

FIG. 4 is an enlarged view of part A of FIG. 3, showing the coupling status between the respective retaining portions and the respective locating portions.

FIG. 5 corresponds to FIG. 3 when viewed from another angle.

FIG. 6 is an enlarged view of part B of FIG. 5.

FIG. 7 is a perspective view illustrating the closed status of the thin type computer according to the present invention.

FIG. 8 is a sectional view taken along line 8-8 of FIG. 7, showing the arrangement between the expansion card and the housing of the thin type computer.

### DETAILED DESCRIPTION OF THE INVENTION

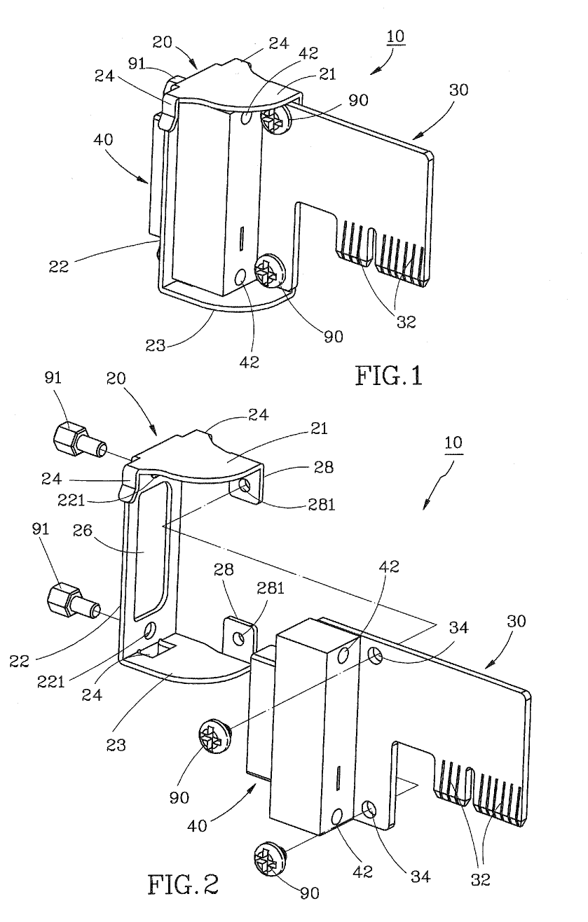

Referring to FIGS. 1 and 2, an expansion card 10 for a thin type computer in accordance with the present invention is shown comprised of a bracket 20, a circuit board 30 and a plug terminal 40.

Bending a metal plate into shape makes the bracket 20. The bracket 20 has a top segment 21, a middle segment 22 and a bottom segment 23. Further, the bracket 20 comprises three retaining portions 24, a through hole 26 and two lugs 28. The retaining portions 24 are protruding ribs. Two retaining portions 24 are respectively extended from two opposite sides of the top segment 21 adjacent to the middle segment 22. The other retaining portion 24 is extended from the bottom side of the middle segment 22 adjacent to the bottom segment 23. The through hole 26 is formed on the middle segment 22 of the bracket 20 between the retaining portions 24 at the top segment 21 and the retaining portion 24 at the bottom side of the middle segment 22. Further, two screw holes 221 are formed on the middle segment 22 of the bracket 20 and respectively disposed at two sides of the through hole 26 adjacent to the top segment 21 and the bottom segment 23. The two lugs 28 are respectively extended from the top segment 21 and the bottom segment 23 remote from the middle segment 22, each having a screw hole 281.

The circuit board 30 comprises a plurality of conducting contacts 32 and two through holes 34. The conducting contacts 32 are arranged on the bottom side of one end of the circuit board 30 for connecting to a thin type computer (not shown) electrically. The two through holes 34 are bilaterally formed on the other end of the circuit board 30, and respectively correspond to one of the screw holes 281 of the lugs 28 of the bracket 20. Thus the bracket 20 and the circuit board 30 can be joined by two screws 90.

The plug terminal 40 is electrically connected to the circuit board 30, having two screw holes 42 corresponding to the two screw holes 221 on the middle segment 22 of the bracket 20. The screw holes 42 of the plug terminal 40 are respectively fastened to the two screw holes 221 on the middle segment 22 of the bracket 20 with a respective screw 91 such that the plug terminal 40 is affixed to the bracket 20.

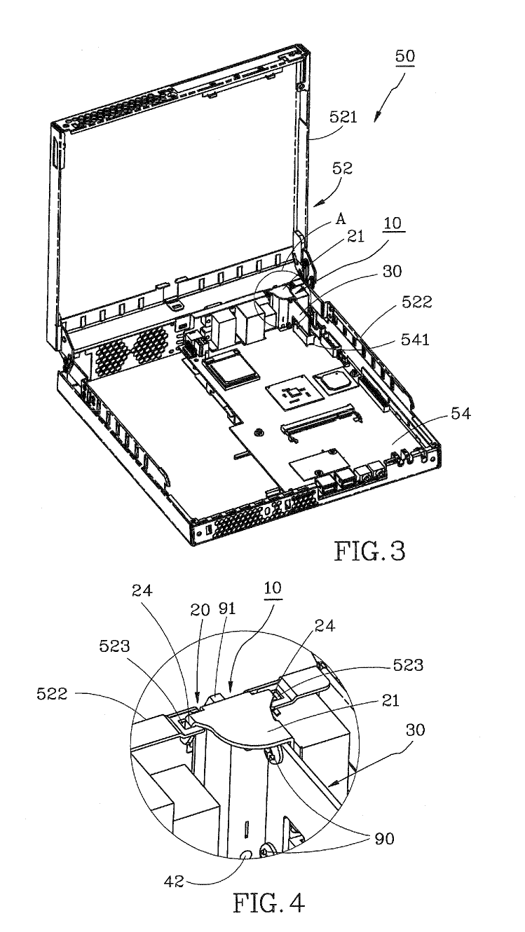

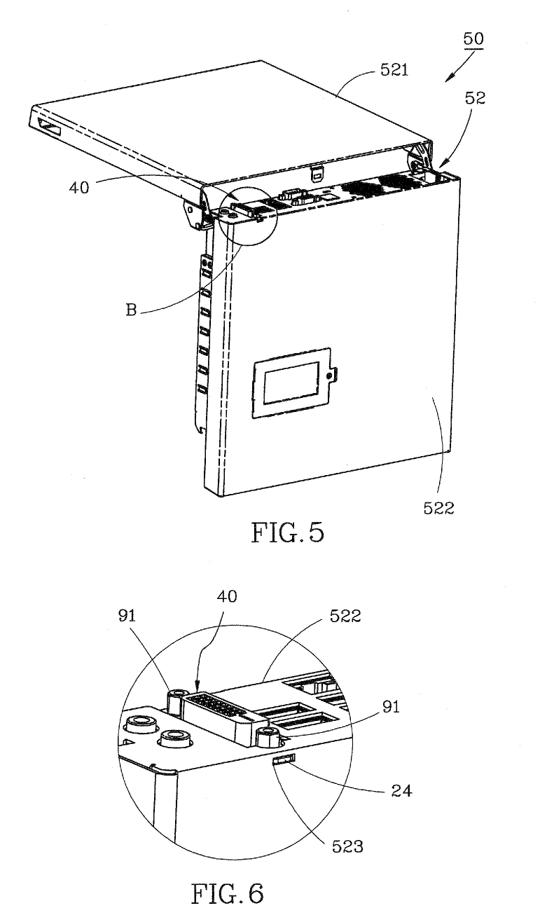

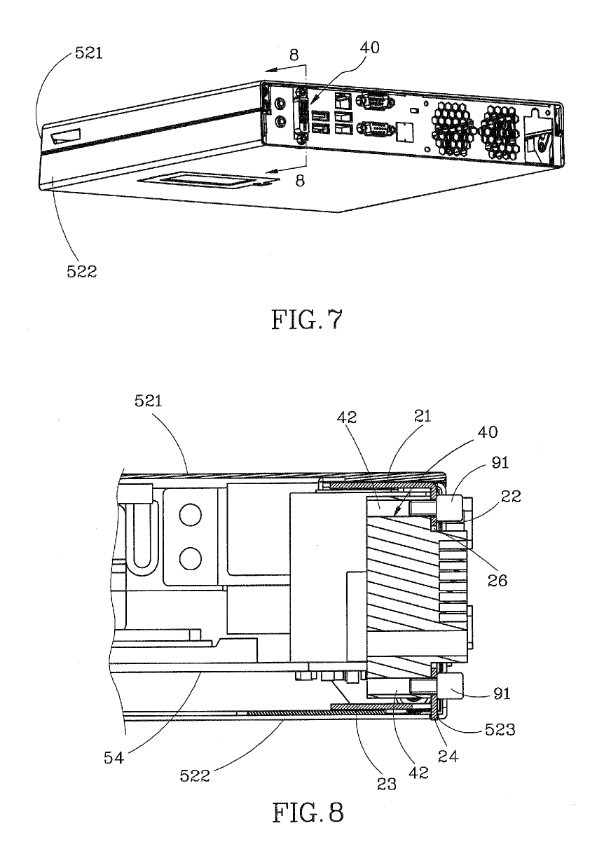

FIGS. 3 through 8 illustrates the expansion card 10 of the present invention used in a thin type computer 50. The thin type computer 50 comprises a housing 52 and a motherboard 54. The housing 52 is comprised of a top cover shell 521 and a bottom cover shell 522. The top cover shell 521 is hinged to the bottom cover shell 522, and turnable relative to the bottom cover shell 522 to close or open the bottom cover shell 522. The bottom cover shell 522 has three locating portions 523. According to the present preferred embodiment, the locating portions 523 are through holes. Two locating portions 523 are respectively positioned at the top side of the bottom cover shell 522 of the housing 52 for receiving the two retaining portions 24 at the top segment 21 of the bracket 20. The other locating portion 523 is provided at the bottom side of the bottom cover shell 522 of the housing 52 for receiving the retaining portion 24 at the bottom segment 23 of the bracket 20. The motherboard 54 is mounted on the bottom cover shell 522 of the housing 52, having a slot 541 at the top side for receiving the conducting contacts 32 of the circuit board 30 to electrically connect the expansion card 10 to the thin type computer 50.

When the user is installing the expansion card 10, one action is enough to have the retaining portions 24 of the bracket 20 be respectively engaged with the locating portions 523 of the housing 52 to prohibit the expansion card 10 from horizontal displacement and to electrically connect the expansion card 10 to the thin type computer 50. At this time, the user can close the top cover shell 521 on the bottom cover shell 522. When the top cover shell 521 is closed on the bottom cover shell 522, the top cover shell 521 is pressed on the top segment 21 of the bracket 20 to prohibit the expansion card 10 from vertical displacement. Thus, the installation of the expansion card 10 is done. After installation of the expansion card 10 in the thin type computer 50, the height of the expansion card 10 is about 45 mm, i.e., about one half of the prior art design.

As stated above, the invention has the following advantages:

1. The invention simplifies the mounting structure of the expansion card, making the installation of the expansion card easy and the use of the expansion card convenient.

2. After installation, the expansion card has a much lower height than the prior art design, and is practical for use in a thin type computer.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. An expansion card for a thin type computer having a housing and a motherboard, said expansion card comprising:
a bracket for mounting to said housing of said thin type computer;
a circuit board mounted on said bracket for electrically connecting to said motherboard; and
at least one plug terminal mounted on said bracket and electrically connected to said circuit board;
wherein the vertical height of both of said bracket and said circuit board above said motherboard is less than 80 mm when the circuit board is connected to said motherboard.

2. The expansion card as claimed in claim 1, wherein said housing of said thin type computer comprises a top cover shell and a bottom cover shell and said expansion card is adapted to be mounted to said bottom cover shell; wherein said top cover shell is closable on said bottom cover shell such that said expansion card is stopped by said top cover shell to prohibit vertical displacement of said expansion card.

3. The expansion card as claimed in claim 1, wherein said bracket has at least one retaining portion for engaging with at least one locating portion of said housing such that said expansion card can be held in place.

4. The expansion card as claimed in claim 3, wherein said bracket has two said retaining portions bilaterally provided at a top side of said bracket remote from said motherboard, and said housing has two said locating portions corresponding to the two retaining portions of said bracket.

5. The expansion card as claimed in claim 3, wherein said retaining portion of said bracket is provided at a bottom side of said bracket adjacent to said motherboard.

6. The expansion card as claimed in claim 3, wherein said retaining portion of said bracket is a protruding rib and said locating portion of said housing is a through hole for receiving said protruding rib.

7. The expansion card as claimed in claim 4, wherein said retaining portion of said bracket is a protruding rib and said locating portion of said housing is a through hole for receiving said protruding rib.

8. The expansion card as claimed in claim 5, wherein said retaining portion of said bracket is a protruding rib and said locating portion of said housing is a through hole for receiving said protruding rib.

9. The expansion card as claimed in claim 1, wherein said bracket has two lugs extending in direction toward said circuit board, said lugs each having a screw hole corresponding to one of two through holes of said circuit board such that said bracket and said circuit board can be joined by two screws.

10. The expansion card as claimed in claim 1, wherein said bracket has at least one through hole for receiving said plug terminal.

11. The expansion card as claimed in claim 1, wherein the vertical height of said expansion card is about 45 mm above said motherboard.

12. The expansion card as claimed in claim 1, wherein said circuit board has a plurality of conducting contacts for electrically connecting said expansion card and said thin type computer.
